(19) United States
(12) Patent Application Publication
(10) Pub. No.: US 2015/0140321 A1
(43) Pub. Date: May 21, 2015

(54) METHODOLOGY FOR IMPROVED ADHESION FOR DEPOSITED FLUORINATED TRANSPARENT CONDUCTING OXIDE FILMS ON A SUBSTRATE

(71) Applicant: Alliance for Sustainable Energy, LLC, Golden, CO (US)

(72) Inventors: Thomas GENNETT, Denver, CO (US); John PERKINS, Boulder, CO (US); Arrelaine DAMERON, Boulder, CO (US)

(21) Appl. No.: 14/542,448

(22) Filed: Nov. 14, 2014

Related U.S. Application Data
(60) Provisional application No. 61/904,594, filed on Nov. 15, 2013.

(51) Int. Cl. C23C 28/04; C23C 16/40

(52) U.S. Cl. CPC C23C 28/04; C23C 16/40
USPC 428/332; 427/126.3; 428/696; 428/432; 428/408; 428/446; 204/192.29

(57) ABSTRACT

A method and device for improving the adhesion of fluorinated transparent conducting oxide films by incorporating a non-conducting, non-fluorinated adhesion layer between a substrate and a transparent conducting oxide.

### PRIORITY

This application claims the benefit under 35 U.S.C. Section 119 of U.S. Provisional Patent Application No. 61/904,594 filed on Nov. 15, 2013 and entitled “Methodology for Improved Adhesion for Deposited Fluorinated Transparent Conducting Oxide Films on a Substrate”, the contents of which are hereby incorporated by reference in its entirety and for all purposes.

The United States Government has rights in this invention under Contract No. DE-AC36-08G028308 between United States Department of Energy and the Alliance for Sustainable Energy, LLC, the Manager and Operator of the National Renewable Energy Laboratory.

### BACKGROUND

Transparent conducting films fabricated from inorganic and organic materials are typically used in various photovoltaic and display devices. Inorganic films typically consist of transition metal materials with a variety of compositions and doping to achieve a transparent conducting film, such as a transparent conductive oxide (TCO). In solar cell applications, the transparent conducting oxides may act as a transparent coating for light to pass through unimpeded to the active absorber material underneath the conducting oxide and/or as an ohmic contact for carrier transport out of a device incorporating the conducting oxide and/or as a barrier layer to keep out atmospheric contaminants (e.g., water, oxygen, dirt, etc.). Similarly, in display applications, transparent conducting oxides act as a transparent top contact that allows the visible light to pass through it unimpeded out of the device and may also serve as a permeation barrier. Transparent conducting oxides currently used in the industry are primarily n-type conductors.

There are several types of transparent conducting oxides that are of commercial importance, such as indium tin oxide (ITO), fluorine doped tin oxide (FTO), tin oxide (SnO), or doped zinc oxide (ZnO). The current industry standard for the generation of transparent conducting oxides generally utilizes indium tin oxide, which is extremely well characterized and exhibits low resistivity and high transmittance. However, indium tin oxide has the drawback of being a very expensive material because indium is a rare post-transition metal (critical material) having a price that can fluctuate greatly due to market demand. For this reason, other doped compounds have been used to produce transparent conducting oxides, including aluminum-doped zinc-oxide, indium-doped cadmium-oxide; fluorine doped tin oxide (FTO), and tin oxide (SnO).

Fluorine-doped metal oxides, like FTOs, are also used in the generation of transparent conducting oxides. However, extreme operating conditions, (>500 C.) are necessary to generate transparent fluorine-doped metal oxide films using existing current commercial manufacturing methods such as spray pyrolysis or chemical vapor deposition processes. These known commercial manufacturing methods when employed at standard atmospheric pressures, tend to yield oxide films with rough and/or diffusive surface morphologies. This produces a great disadvantage to the resulting conducting oxides, because the transmittance of these materials can be dramatically decreased by light scattering at defects and grain boundaries on the oxide film. For example, during deposition of fluorine-doped tin oxide onto a target substrate, typical chemical vapor deposition processes can cause the tin to agglomerate and collect in lumps along the substrate surface. Such defects not only result in poor transparency, as the fluorine-doped tin oxide coating looks hazy, but can also limit the transmittance of such films due to light scattering at the points of defect. Additionally, the resulting conducting tin oxide films are poor substrates for most semiconductor chips and other electrical devices as they can hinder and/or reduce their conductive performance.

Further, most known deposition processes, like spray pyrolysis or chemical vapor deposition, require very high operating temperatures, typically on the order of 400° C. to 600° C. Achieving such high temperatures requires a large amount of energy and can be expensive to maintain for long periods of time. Additionally, such elevated temperatures tend to cause damage to the underlying layers and or substrate in or under the multilayer devices having a conducting oxide top layer, which has deleterious effects on device performance. It has been recently discovered that fluorinated metal oxide films, like FTOs, can also be produced via sputter deposition at room temperature. However, commercial use of sputtered fluorinated metal oxides, like FTOs, is further limited because these particular fluorinated metal oxides tend to delaminate from a substrate surface. For these reasons, the use of fluorine-doped metal oxides as a top layer conductor for semiconductors, photovoltaic cells, and similar devices has been limited.

A need exists for a method of producing (for example, by sputter deposition), a fluorinated TCO material such as tin oxide (SnO) that possesses high transparency and high conductivity and that also minimizes or otherwise reduces the drawbacks associated with existing delamination issues. The insights gained from this method may be further applied to the production of other fluorine-doped TCOs. The TCO materials produced using such a method may be used to produce higher-efficiency photovoltaic cells resulting from the enhanced optical transparency of the resulting fluorine-doped TCO film that remains attached to the substrate, including when the substrate is a flexible material, plastic or a metal foil. Thus, this method may be used to produce a TCO film such as a fluorine-doped tin oxide on a commercial scale, which may be used in the large-scale production (e.g., roll-to-roll processing) of highly efficient photovoltaic cells, among other uses.

The foregoing examples of the related art and limitations related therewith are intended to be illustrative and not exclusive. Other limitations of the related art will become apparent to those of skill in the art upon a reading of the specification and a study of the drawings.

### BRIEF DESCRIPTION OF DRAWINGS

Exemplary embodiments illustrated in referenced figures of the drawings. It is intended that the embodiments and figures disclosed herein are to be considered illustrative rather than limiting. Those skilled in the art will understand that the drawings, described herein, are for illustration purposes only. The drawings are not intended to limit the scope of the present disclosure.

FIG. 1 is a schematic diagram illustrating the incorporation of an adhesion layer of an exemplary photovoltaic device using a method described herein.

FIG. 2 illustrates a method for forming an adhesion layer disposed between a fluorinated transparent conducting oxide layer and a substrate as described herein.

FIG. 3 is a collection of photographs of substrates with and without incorporating an adhesion layer using a method described herein.

### DETAILED DESCRIPTION

The following embodiments and aspects thereof are described and illustrated in conjunction with systems, tools and methods which are meant to be exemplary and illustrative, not limiting in scope. In various embodiments, one or more of the above-described problems have been reduced or eliminated, while other embodiments are directed to other improvements.

One aspect of the present disclosure involves a method of incorporating an adhesion layer disposed between a substrate and a deposited halogenated transparent conducting oxide. The method involves depositing a thin, non-conducting layer within a sputter processing chamber (or other thin film deposition system) on to a substrate, forming a thin adhesion layer. Additionally, the method involves depositing a halogenated transparent conducting oxide, onto the adhesion layer, wherein the transparent conducting oxide is halogen-containing, to form a transparent halogen-containing metal oxide film on to the substrate. In some embodiments, the method involves the sputter deposition of a thin, non-fluorinated, non-conducting oxide layer within a sputter processing chamber, on to the substrate, forming a thin oxide-containing adhesion layer. In some embodiments, the transparent conducting oxide is fluorinated. In some aspects, the transparent conducting oxide is tin oxide doped with CF₄, diluted fluorine gas, or any combinations thereof. The method may further involve the step of annealing the transparent halogen-containing metal oxide film onto the substrate. Another aspect of the present disclosure involves a device comprising at least one adhesion layer disposed between a substrate and a deposited halogenated transparent conducting oxide layer produced using the methods discussed herein, wherein the device is a photovoltaic cell, solar cell, thin film transistor, optoelectronic device, and/or any other known devices requiring the use of a transparent conducting oxide film. Alternatively, the method described herein may comprise the use of sulfides, nitrides, oxides or any combination thereof

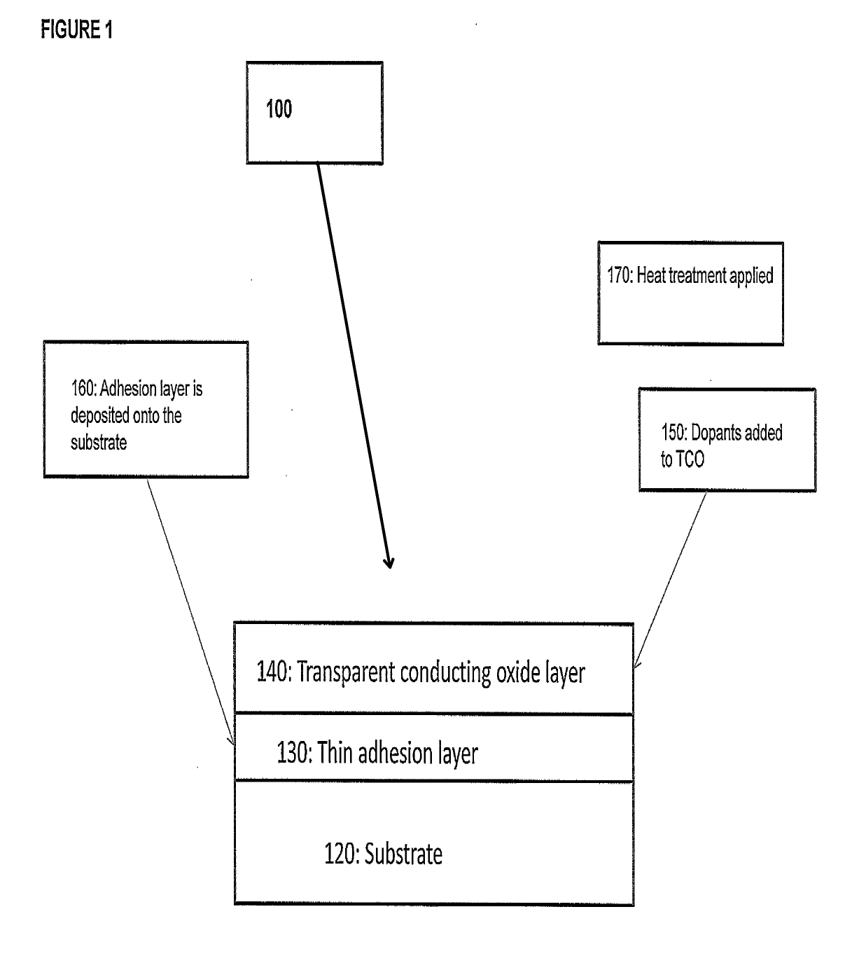

In some embodiments, and with reference to the general disclosure provided in FIG. 1, an adhesion layer may be used in the construction of a thin film photovoltaic cell. In the thin film photovoltaic cell 100, an un-doped, non-conducting oxide layer may be used as an adhesion layer 130 between the resultant transparent conducting metal oxide film layer 140, such as conductive fluorine-doped tin oxide layer, and substrate 120. In some aspects, the present disclosure relates to the generation of an adhesion layer 130 disposed between a substrate 120 and transparent conducting metal oxide film 140, which in some embodiments, the adhesion layer 130 can be a non-metal or metal oxide.

In an exemplary embodiment, the adhesion layer 130 includes any compound containing one or more metals to be included in the adhesion layer. Non-limiting examples of metals suitable for inclusion in adhesion layer 130 include tin (Sn), cadmium (Cd), zinc (Zn), indium (In), nickel (Ni), zirconium (Zr), vanadium (V), titanium (Ti), copper (Cu), and hafnium (Ha). The metal may be delivered by sputtering the metal directly from a solid metal, plasma, or metal oxide target. In other embodiments, the metal is delivered by using a liquid or vapor-phase organometallic precursor. Alternatively, the metal-containing adhesion layer may comprise one or more metals covalently, ionically or physically adhered to one or more attached groups, including, but not limited to, oxides, alkanes, alkenes, alkynes, alcohols, halogens, ketones, aldehydes, carboxylic acids, ethers, esters, amines, amides, ketones, aldehydes, oxygen, and perhalogenated alkyls. In some embodiments, the adhesion layer 130 is non-fluorinated. In other embodiments, the adhesion layer 130 is non-conducting. The adhesion layer 130 may be deposited 160 by a variety of methods such as chemical vapor deposition (CVD), atomic layer deposition (ALD), sputtering, spray pyrolysis or any other deposition processes known in the art. In some embodiments, the thickness of the adhesion layer 130 is less than the transparent conducting metal oxide film 140. In some aspects, the thickness of the adhesion layer 130 is in the range from about 10 nm to about 30 nm. In other aspects, the thickness is less than about 10 nm, such as about 9 nm, about 8 nm, about 7 nm, about 6 nm, about 5 nm, about 4 nm, about 3 nm, or about 2 nm. In some embodiments, the adhesion layer is a continuous or non-continuous film. In other embodiments, the adhesion layer is amorphous.

In an exemplary embodiment, the TCO material used to generate the resultant transparent conducting metal film 140 can be any one or more of a number of metals, semimetals, metalloids, or metal oxides suitable for generation of transparent conducting metal oxide films. In some embodiments, the TCO material is selected from indium oxide, zinc oxide, cadmium oxide, tin oxide, and combinations thereof. In some embodiments, the TCO material is selected from an oxide of any one or more of the Period 3, Period 4 and/or Period 5 transition metals including, without limitation, scandium oxide, titanium oxide, vanadium oxide, chromium oxide, manganese oxide, iron oxide, cobalt oxide, nickel oxide, copper oxide, zinc oxide, gallium oxide, germanium oxide, yttrium oxide, zirconium oxide, niobium oxide, molybdenum oxide, technetium oxide, ruthenium oxide, rhodium oxide, palladium oxide, silver oxide, cadmium oxide, indium oxide, tin oxide, antimony oxide, and combinations thereof. Other non-limiting examples of TCOs materials suitable for production using this method include silicon oxide, aluminum oxide, lanthanum oxide, indium-tin oxide, Pb—Zr—Ti oxide and other piezo-electric ceramics, carbon, silicon nitride, and super-conducting materials such as mercury-barium oxide, and mercury-barium-copper oxide. In the embodiment depicted in FIG. 1, the metal oxide TCO film 140 is tin oxide and/or fluorine-doped tin oxide. In some embodiments, the metal oxide TCO film 140 is a tin-containing material. The tin-containing material can be any one or more of solid tin metal, a tin oxide material, a tin fluoride (SnF₂) material, or combinations thereof

In some aspects, the TCO material may also be a doped metal oxide, in which the inclusion of dopants 150 is used to alter the inherent electrical properties of the un-doped TCO material. In some embodiments, halogen or halogen-containing gases can be introduced to form a dopant for the TCO material. The dopant precursor may comprise one or more dopant elements, either alone or in combination with other elements, including, but not limited to, carbon, oxygen, nitrogen, sulfur, boron and/or halogens, among other elements. The dopant precursor may include one or more metal groups, including the metal to be incorporated into the TCO material to be produced using the method. The dopant precursor may be provided as a single compound, or as a mixture of two or more dopant precursor compounds. Any of the TCO materials described above may be doped with one or more elements including, but not limited to, Group V and Group VII elements.

The doped transparent conducting metal oxide can be generated from any one or more of many doped metal oxides. In some embodiments, the doped transparent conducting metal oxide is generated from one or more doped metal oxides selected from tin-doped indium-oxide, aluminum-doped zinc-oxide, indium-doped cadmium-oxide, fluorine-doped tin-oxide, and combinations thereof. In some embodiments, the doped transparent conducting metal oxide is generated from un-doped metal oxides, where a reactive sputtering process induces the halogen within the process gas by the addition of a pure or composite halogen gas. In some embodiments, when the halogen gas target is fluorine, CF₄ and/or F₂ can be utilized. In some embodiments, the doped transparent conducting metal oxide is generated from one or more halogen doped oxides of any one or more of the Period 3, 4 or Period 5 transition metals including, without limitation, halogen doped scandium oxide, halogen doped titanium oxide, halogen doped vanadium oxide, halogen doped chromium oxide, halogen doped manganese oxide, halogen doped iron oxide, halogen doped cobalt oxide, halogen doped nickel oxide, halogen doped copper oxide, halogen doped zinc oxide, halogen doped gallium oxide, halogen doped germanium oxide, halogen doped yttrium oxide, halogen doped zirconium oxide, halogen doped niobium oxide, halogen doped molybdenum oxide, halogen doped technetium oxide, halogen doped ruthenium oxide, halogen doped rhodium oxide, halogen doped palladium oxide, halogen doped silver oxide, halogen doped cadmium oxide, halogen doped indium oxide, halogen doped tin oxide, halogen doped antimony oxide and combinations thereof. The halogen dopant may be one or more of any of the known halogen or halogen-containing gases.

In some embodiments, the halogen gases are selected from fluorine gas, chlorine gas, bromine gas, iodine gas, astatine gas and combinations thereof and the halogen-containing gases are selected from carbon tetrafluoride gas, carbon tetrachloride gas and combinations thereof. In some embodiments, the halogen gas is fluorine gas. In some embodiments, the halogen-containing gas is carbon tetrafluoride. In some embodiments, the halogen gases are a mixture of gases, both halogen containing, and/or halogen and non-halogen containing, such as Argon and/or CF₄, and/or F₂. In some embodiments, the doped transparent conducting metal oxide is generated from a halogen doped tin oxide target. In some embodiments, when fluorination of the metal oxide is desired, it can occur by incorporation of CF₄, mixing tin fluoride with tin oxide or diluting fluorine with argon gas, or any other methods wherein fluorination is desired. As an alternative embodiment depicted in FIG. 1, the TCO metal film 140 produced using the method is a fluorine-doped tin oxide (F:SnO₂).

In various aspects, the halogen dopant may be introduced during the sputtering process, wherein one or more halogen gases, and/or one or more halogen-containing gases, can be introduced into the sputtering chamber. The metal-containing precursor may be diluted in a carrier gas. Non-limiting examples of suitable carrier gases include inert gases such as N₂, He, and Ar, and gases with a combination of inert and reactive compounds such as air (O₂). When such gases are introduced, the energy present in the sputtering chamber from the one or more energy sources can cause the halogen to dissociate from the halogen gases and/or from the halogen-containing gases, where it will act as a dopant for the growing transparent conducting metal oxide film 140.

The method described herein may make use of any known method of depositing a TCO metal film, including, but not limited to, chemical vapor deposition (CVD), spray pyrolysis, and sputtering. The particular deposition method used depends upon the desired process conditions, such as chamber temperature and pressure, the desired composition of the TCO metal film, and the presence and amount of other precursors. An exemplary processing method is sputter deposition. When the sputtering method is utilized, a transparent conducting metal oxide film having high conductivity can be generated on a substrate surface. In some embodiments, a transparent conducting metal oxide film can be generated via a sputtering process performed at room temperature. Typically sputtering is carried out inside of a chamber so that the environment within the chamber can be controlled. It is common for sputtering to occur in a chamber that is under sub-ambient pressures. The sputtering process is thus initiated by applying power, in the form of an energy source, to a target material. The energy source can be of any type that generates sufficient momentum between neighboring atoms to free them from the target material including, for example, pulsed direct current (DC), non-pulsed DC, radio frequency (RF) energy, and RF energy superimposed with DC, among others. The duration of the sputtering process controls the thickness of the transparent conducting oxide film. Shorter sputtering times yield thin films while longer sputtering times yield thicker films. The sputtering process continues until the transparent conducting metal oxide film 140 of a desired thickness is grown on the substrate 120. The method described herein may also include a transparent conducting layer that is amorphous, textured, ordered and/or crystalline.

Thus, alternate methods of generating transparent conducting oxides, such as sputtering techniques and/or sputtering techniques followed by a heat treatment 170, such as an annealing step, are useful. In some embodiments, after the sputtering process is complete the transparent conducting metal oxide film 140 is annealed. Annealing improves the conductivity of the transparent conducting oxide film. Annealing is a heat treatment process that alters certain properties of the transparent conducting oxide film, such as strength and hardness. Annealing occurs by the diffusion of atoms within the transparent conducting metal oxide film in response to the addition of heat energy, so that the film progresses toward its equilibrium state. Both the time and temperature of the annealing step can be altered. In some embodiments, annealing can occur for a period of time ranging from about 1 minute to about 30 minutes. In some embodiments, annealing can occur for a period of time selected from about 30 minutes, about 25 minutes, about 20 minutes, about 15 minutes, about 10 minutes, about 5 minutes, about 4 minutes, about 3 minutes, about 2 minutes and about 1 minute. In some embodiments, annealing can occur in seconds, by traditional metallurgical annealing or by a combination of annealing ramps and holds (heat conditioning). In some embodiments, the annealing can occur at a temperature ranging from about 100° C. to about 500° C. In some embodiments, the annealing can occur at a temperature ranging from about 250° C. to about 500° C. In some embodiments, the annealing can occur at a temperature selected from about 500° C., about 450° C., about 400° C., about 350° C., about 300° C., about 250° C., about 200° C., about 150° C., about 100° C., and about 50° C.

The substrate material 120 can be any one or more of a number of substrates suitable for deposition of transparent conducting metal oxide film 140. In some embodiments, the substrate is selected from glass, ceramic, plastic, silicon wafer material, and related materials. In some embodiments, the substrate is a photovoltaic cell. In some embodiments, the substrate is a semiconductor. In some embodiments, the substrate is a wafer. The substrate may be, but not limited to, soda-lime glass, silica, or various glass compositions such as borosilicate, alumniosilicate, or barium silicate, pre-coated with various coatings or other barrier coatings, un-doped TCO coatings such as tin oxide (SnO), cadmium oxide (CdO), cadmium tin oxide (Cd₂SnO₄), zinc oxide (ZnO), and indium tin oxide (In₂O₃:Sn). In some embodiments, the substrate is flexible material, such as plastic or flexible glass, metal foil, ceramic deposited on a foil, a plastic spacer layer or any combination thereof. The selection of substrate may be based on any one of at least several factors, including, but not limited to, the material properties of the substrate at the temperatures at which the TCO film is deposited, the reactivity of the substrate surface with the precursor compounds during deposition, and the intended use of the TCO film.

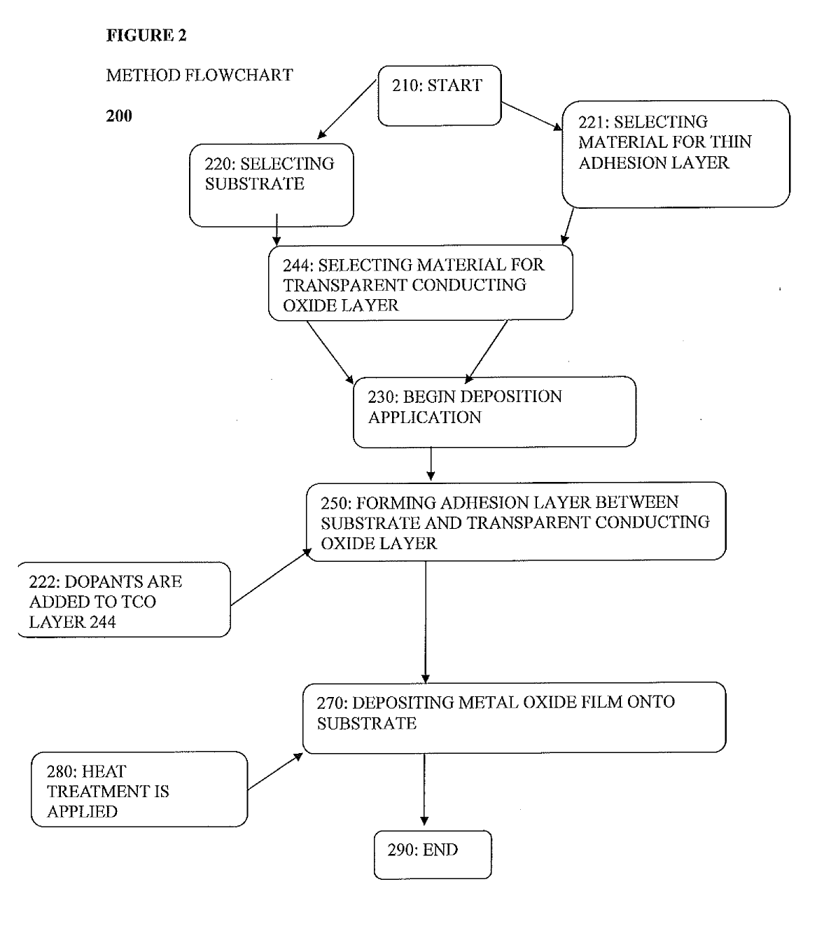

FIG. 2 is a flow diagram illustrating at 200 an exemplary method embodiment for incorporating an adhesion layer deposited onto a substrate with a fluorinated transparent conducting metal oxide film as described herein. The method begins at 210 by designing a particular device to be fabricated. The method continues with selecting material for the substrate at 220, selecting material for the thin adhesion layer at 221, and selecting material for the transparent conducting oxide layer at 244. At 230, the method may, or may not include the deposition application of the three layers. The method continues at 250 with forming the adhesion layer between the substrate and the transparent conducting oxide layer. At 270, the method further continues with depositing the TCO film on to the substrate 250. In some embodiments, the method may include adding dopants to the TCO at 222 or applying a heat treatment to the TCO film at 280.

The selection of the material for the thin adhesion layer at 221 includes the selection of any compound containing one or more metals to be included in the adhesion layer. Non-limiting examples of metals suitable for inclusion include tin (Sn), cadmium (Cd), zinc (Zn), indium (In), nickel (Ni), zirconium (Zr), vanadium (V), titanium (Ti), copper (Cu), and hafnium (Ha). The metal may be delivered by sputtering directly from a solid metal, plasma, or metal oxide target. In other embodiments, the metal is delivered by using a liquid or vapor-phase organometallic precursor. Alternatively, the metal-containing adhesion layer may comprise one or more metals covalently, ionically or physically adhered to one or more attached groups, including, but not limited to, oxides, alkanes, alkenes, alkynes, alcohols, halogens, ketones, aldehydes, carboxylic acids, ethers, esters, amines, amides, ketones, aldehydes, oxygen, and perhalogenated alkyls. In some embodiments, the adhesion layer selected at 221 is non-fluorinated. In other embodiments, the adhesion layer selected at 221 is non-conducting. The adhesion layer selected at 221 may be deposited at 230 by a variety of methods such as chemical vapor deposition (CVD), atomic layer deposition (ALD), sputtering, spray pyrolysis or any other deposition processes known in the art. In some embodiments, the thickness of the adhesion layer is less than the transparent conducting metal oxide film 244. In some aspects, the thickness of the adhesion layer is between about 10-30 nm. In other aspects, the thickness is less than 10 nm, such as 2 nm. In some embodiments, the adhesion layer is a continuous or non-continuous film. In other embodiments, the adhesion layer is amorphous. In some embodiments, the metal oxide TCO film (or layer) selected at 244 is tin oxide and/or fluorine-doped tin oxide. In some embodiments, the metal oxide TCO film 244 is a tin-containing material. The tin-containing material can be any one or more of solid tin metal, a tin oxide material, a tin fluoride (SnF₂) material, or combinations thereof

The substrate material selected at 220 can be any one or more of a number of substrates suitable for the deposition of transparent conducting metal oxide film at 244. In some embodiments, the substrate is selected from glass, ceramic, plastic, silicon wafer material, and related materials. In some embodiments, the substrate is a photovoltaic cell. In some embodiments, the substrate is a semiconductor. In some embodiments, the substrate is a wafer. The substrate may be, but not limited to, soda-lime glass, silica, or various glass compositions such as borosilicate, alumniosilicate, or barium silicate, pre-coated with various coatings or other barrier coatings, un-doped TCO coatings such as tin oxide (SnO), cadmium oxide (CdO), cadmium tin oxide (Cd₂SnO₄), zinc oxide (ZnO), and indium tin oxide (In₂O₃:Sn). In some embodiments, the substrate is flexible material, such as plastic or flexible glass. In some embodiments, the substrate may be a finished photovoltaic, optoelectronic device, or any combination thereof. The selection of substrate may be based on any one of at least several factors, including, but not limited to, the material properties of the substrate at the temperatures at which the TCO film is deposited, the reactivity of the substrate surface with the precursor compounds during deposition, and the intended use of the TCO film. The method then may end at 290.

The following example describes in detail certain properties of embodiments of transparent conducting metal oxides prepared by sputter deposition as disclosed herein. It will be apparent to those skilled in the art that many modifications, both to materials and methods, may be practiced without departing from the scope of the disclosure.

### EXAMPLE 1

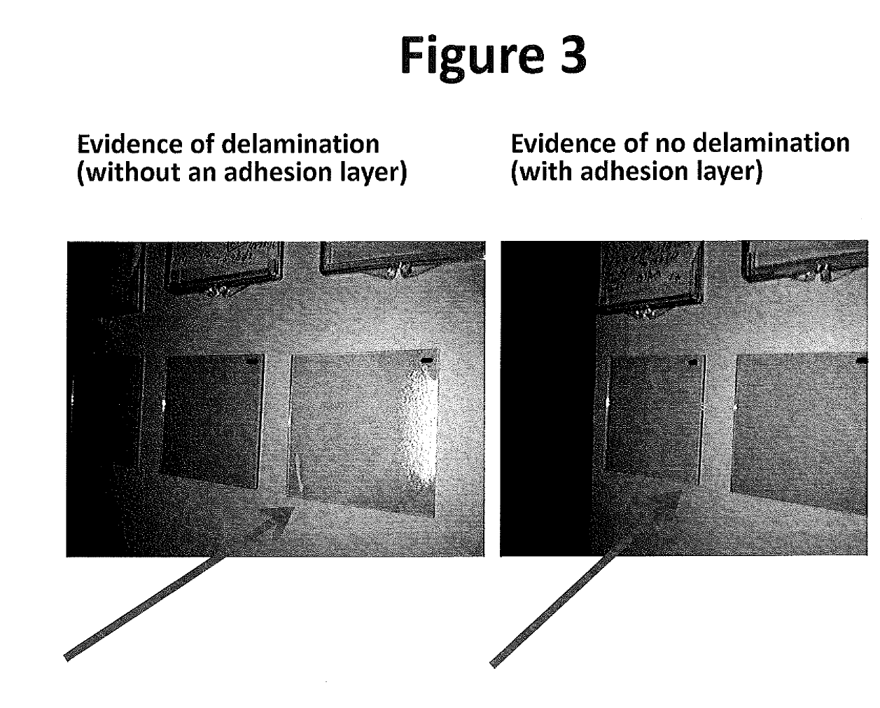

The deposition of a fluorinated film to a glass substrate with and without an adhesion film was conducted via a sputter deposition process performed at a temperature of about 200° C. using an RF energy source of about 200 watts. The total pressure in the sputtering chamber was reduced to 4.5 mT. The samples had a thickness in the range from about 200 nm to about 1000 nm. As shown in FIG. 3a, the exemplary transparent conducting metal oxide film did not show any delamination, as opposed to the exemplary transparent conducting metal oxide film shown in FIG. 3b, which did not incorporate an adhesion layer and subsequently exhibited delamination.

The TCO materials produced using such a method may be used to produce higher-efficiency photovoltaic cells resulting from the enhanced optical transparency of the resulting TCO film that remain attached to the substrate by incorporating a non-fluorinated, non-conducting adhesion layer. Adhesion of the TCO film is desired, especially when the substrate is a flexible material, plastic or a metal foil. Thus, this method may be used to produce a TCO film such as a fluorine-doped tin oxide on a commercial scale, which may be used in the large-scale production (e.g., roll-to-roll processing) of highly efficient photovoltaic cells, among other uses. Most known deposition processes, like spray pyrolysis or chemical vapor deposition, require very high operating temperatures, typically on the order of 400° C.-600° C. Achieving such high temperatures requires a large amount of energy and can be expensive to maintain for long periods of time. Additionally, such elevated temperatures tend to cause damage to the underlying layers and or substrate in or under the multilayer devices having a conducting oxide top layer, which has deleterious effects on device performance. The incorporation of the adhesion layer as described herein will allow for the deposition of fluorinated metal oxides, such as by sputter deposition, at greatly reduced temperatures.

The method and apparatus described herein can be used in a variety thin film structures, such as a silicon solar cell structure (including as silicon contacts), dye-sensitized solar cell, a CIGS solar cell configuration, an organic solar cell, or other known photovoltaic structures. The use of TCOs in thin film devices include, liquid crystal display, thin film solar cells, light emitting diodes, transparent thin film transistors, or any other known devices. The TCO film may be used in any glass, polymer, foil, or electronic device in which there is a desire or need for sputtered transparent conducting metal oxide films produced at room temperature and remains attached to the substrate.

Further, transparent conducting metal oxide films produced according to the disclosed methods can be prepared and deposited onto numerous substrates that were previously unable to be coated by other processes, such as spray pyrolysis or CVD processes, because the substrate materials could not withstand the high temperatures required for such processes. The disclosed inclusion of an adhesion layer with sputtering deposition processes opens up many options for low cost coating of a variety of substrates with transparent conducting oxides having relatively high conductivity for a variety of electrical, optical, and semiconductor materials, among others.

Finally, it should be noted that there are alternative ways of implementing the embodiments disclosed herein. While a number of exemplary aspects and embodiments have been discussed above, those of skill in the art will recognize certain modifications, permutations, additions and sub combinations thereof. Accordingly, the present embodiments are to be considered as illustrative and not restrictive. Furthermore, the claims are not to be limited to the details given herein, and are entitled their full scope and equivalents thereof

What is claimed is:

1. A device with improved adhesion of a fluorinated transparent conducting oxide layer to a substrate comprising:
a substrate;
at least one non-fluorinated metal oxide thin film deposited on the substrate; and
at least one halogenated transparent conducting oxide layer deposited on the thin film, wherein the non-fluorinated metal oxide film adheres the conducting oxide layer to the substrate.

2. The device of claim 1, wherein the metal of the non-fluorinated metal oxide thin film comprises at least one of tin, cadmium , zinc, indium, nickel, zirconium, vanadium, titanium, copper, hafnium, or combinations thereof.

3. The device of claim 2, wherein the metal of the non-fluorinated metal oxide thin film comprises at least one of tin, zinc, titanium, or combinations thereof

4. The device of claim 1, wherein the metal oxide thin film deposited on the substrate comprises a non-halogenated metal oxide thin film.

5. The device of claim 1, wherein the thin film comprises a thickness ranging from about 2 nm to about 30 nm.

6. The device of claim 1, wherein the substrate comprises at least one of glass, quartz, sapphire, SiC, diamond, ceramic, plastic, silicon, a silicon wafer, a photovoltaic cell, a semiconductor, or combinations thereof

7. The device of claim 1, wherein the halogenated transparent conducting oxide layer comprises at least one of scandium oxide, titanium oxide, vanadium oxide, chromium oxide, manganese oxide, iron oxide, cobalt oxide, nickel oxide, copper oxide, zinc oxide, gallium oxide, germanium oxide, yttrium oxide, zirconium oxide, niobium oxide, molybdenum oxide, technetium oxide, ruthenium oxide, rhodium oxide, palladium oxide, silver oxide, cadmium oxide, indium oxide, tin oxide, antimony oxide, silicon oxide, aluminum oxide, lanthanum oxide, indium-tin oxide, Pb—Zr—Ti oxide, or combinations thereof

8. The device of claim 7, wherein the halogenated transparent conducting oxide layer comprises at least one of indium oxide, zinc oxide, cadmium oxide, tin oxide, or combinations thereof

9. The device of claim 8, wherein the halogenated transparent conducting oxide layer consists of tin oxide.

10. The device of claim 1, wherein the halogen of the halogenated transparent conducting oxide layer comprises at least one of fluorine, chlorine, iodine, bromine, astatine, or mixtures thereof

11. The device of claim 10, wherein the halogen consists of fluorine.

12. A device with improved adhesion of a fluorinated transparent conducting oxide layer to a substrate comprising:
a glass substrate;
a non-fluorinated tin oxide thin film deposited on the substrate, comprising a thickness ranging from about 2 nm to about 30 nm; and
a transparent fluorine doped conducting tin oxide layer deposited on the thin film, wherein the thin film adheres the transparent conducting oxide layer to the substrate.

13. A method for improving the adhesion of a fluorinated transparent conducting oxide film to a substrate, the method comprising:
providing a substrate;
depositing a thin non-fluorinated metal oxide film onto the substrate ;
depositing a halogen doped transparent conducting oxide layer on to the film, wherein the non-fluorinated metal oxide film adheres the conducting oxide layer to the substrate.

14. The method of claim 13, wherein depositing the thin film on the substrate is by at least one of sputter deposition, chemical vapor deposition, atomic layer deposition, spray pyrolysis, or combinations thereof

15. The method of claim 14, wherein depositing the thin film on the substrate is by sputter deposition or atomic layer deposition.

16. The method of claim 15, wherein depositing the thin film is by sputter deposition in a chamber under vacuum.

17. The method of claim 13, wherein depositing the conducting oxide layer on the thin film is by at least one of sputter deposition, chemical vapor deposition, atomic layer deposition, spray pyrolysis, or combinations thereof.

18. The method of claim 17, wherein depositing the conducting oxide layer on the thin film is by sputter deposition in a chamber under vacuum.

19. The method of claim 18, wherein the sputter deposition is initiated by applying an energy source, wherein the energy source comprises at least one of pulsed direct current (DC), non-pulsed DC, alternating current (AC), high frequency AC, radio frequency (RF), or combinations thereof

20. The method of claim 17, wherein depositing the conducting oxide layer further comprises providing the halogen in the form of a gas comprising at least one of fluorine, chlorine, bromine, iodine, astatine, carbon tetrafluoride, carbon tetrachloride, or mixtures thereof
